(19) United States
(12) Patent Application Publication
(10) Pub. No.: US 2025/0392269 A1
(43) Pub. Date: Dec. 25, 2025

(54) LC RESONATOR FOR CASCODE AMPLIFIER STABILITY

(71) Applicant: pSemi Corporation, San Diego, CA (US)

(72) Inventors: Ahmet Hakan COSKUN, SAN DIEGO, CA (US); Emre AYRANCI, SAN DIEGO, CA (US); Sandro BRENCIAGLIA, SAN DIEGO, CA (US)

(21) Appl. No.: 18/750,533

(22) Filed: Jun. 21, 2024

(51) Int. Cl. H03F 3/19

(52) U.S. Cl. CPC H03F 3/19; H03F 2200/451

(57) ABSTRACT

A cascode amplifier with stability compensation network for removing instabilities of the amplifier due to cascode gate inductance is presented. The stability compensation network is a LC resonator with a resonance that targets a frequency of instability of the cascode amplifier. At the frequency of instability, the LC resonator is a short. The LC resonator is coupled in parallel to the gate inductance and a corresponding gate capacitance. According to one aspect, the gate inductance is a parasitic inductance. According to another aspect, the gate inductance further includes a gain boosting gate inductance. The gate boosting inductance provides a gain boost at a frequency of operation of the cascode amplifier. According to one aspect, values of an inductor and/or capacitor of the LC resonator are iteratively derived based on an optimization routine with criteria that includes a magnitude of a k- or μ-factor.

### TECHNICAL FIELD

The present application is related to electronic radio frequency (RF) circuits, and more particularly to stability enhancement for cascode amplifiers.

### BACKGROUND

FIG. 1 shows a simplified schematic of a prior art amplifier (100) that may be used, for example, in a receive or transmit side of an RF system, such as, for example, an RF frontend (RFFE). In such an RF system, part of, for example, a handheld device, the amplifier (100) may amplify an input RF signal, RF_{IN}, to the amplifier (100) to output a corresponding amplified output RF signal, RF_{OUT}. When operating in a receive side of the RF system, the input RF signal, RF_{IN}, may be an RF signal received at an antenna and the amplifier (100) may be referred to as a low noise amplifier (LNA), and when operating on a transmit side of the RF system, the output RF signal, RF_{OUT}, may be an RF signal transmitted at the antenna and the amplifier (100) may be referred to as a power amplifier (PA). Processing (e.g., amplification) of the input RF signal, RF_{IN}, may be provided through a cascode configuration (M1, M2, a cascode arrangement, a cascode amplifier) comprising an input transistor, M1, that is in series connection with an output cascode transistor, M2. As known to a person skilled in the art, DC biasing of the cascode configuration (M1, M2) may be provided via (gate) biasing signals (V_{G1}, V_{G2}) provided/coupled (e.g., via one or more of, for example, inductor, resistor, transformer, switch, etc.) to gates of the transistors (M1, M2), in combination with a supply voltage, V_{DD}, that is coupled to a drain of the output cascode transistor, M2, through an inductor, L_{OUT}, and a reference ground, Gnd, that is coupled to a source, S1, of the input transistor, M1, through, for example, an optional degeneration inductor, L_{DEG}. A person skilled in the art would recognize that the input transistor, M1, is configured as a common source transistor, and the output cascode transistor, M2, is configured as a common gate transistor. In the exemplary case where the amplifier (100) is configured as an LNA that may include the degeneration inductor, L_{DEG}, the amplifier (100) may be referred to as an inductively degenerated common source LNA.

With continued reference to FIG. 1, the prior art amplifier (100) may include an input match circuit, M_{IN}, coupled to the input transistor, M1, and an output match circuit, M_{OUT}, coupled to the output cascode transistor, M2. Each of the input and output match circuits, M_{IN} and M_{OUT}, may include reactive and/or resistive elements configured to reduce, at a desired operating frequency (e.g., a frequency band of operation) of the amplifier (100), loss of RF signal power/magnitude (e.g., input/output return loss). As shown in FIG. 1, in the exemplary case of an LNA, the input match circuit, M_{IN}, may include an inductor, LIN, in series connection with a gate, G₁, of the input transistor, M1. Furthermore, the input and output match circuits, M_{IN} and M_{OUT}, may be coupled to the (gate of the) input transistor, M1, and the (drain of the) output cascode transistor, M2, through respective AC coupling capacitors, CIN and Cour. In some cases, multi-gain functionality of the amplifier (100) may be provided by changing (e.g., tuning, switching) impedance provided by the input and/or output matching circuits, M_{IN} and/or M_{OUT}.

As it is well known to a person skilled in the art, coupled to a gate, G₂, of the output cascode transistor, M2, there may be a (shunting) gate capacitor, C_{G2}, that is configured to shunt the gate, G₂, to the reference ground, Gnd, at the frequency (band) of operation of the amplifier (100). In other words, an impedance/reactance of the gate capacitor, C_{G2}, at the frequency of operation of the amplifier (100) may be substantially zero, thereby shorting the gate, G₂, to the reference ground, Gnd. As shown in detail a of FIG. 1, further coupled to the gate, G₂, there may be a (series-connected) parasitic gate inductance, L_{PAR}, that represents a combination of parasitic contributions from, for example, physical structures of conductors used for routing of signals and/or layout of components/elements of the amplifier (100) and/or related circuits as part of, e.g., an integrated circuit or a module. The parasitic gate inductance, L_{PAR}, may encompass, for example, an inductance of a trace connecting the gate, G₂, to the gate capacitor, C_{G2}, an inductance of a trace connecting the gate capacitor, C_{G2}, to the reference ground, Gnd, and a (series) parasitic inductance of the gate capacitor, C_{G2}.

When operating the amplifier (100) at higher frequencies (e.g., 1 GHz and above, up to 100 GHz) as required by current and/or upcoming communication standards, the parasitic gate inductance, L_{PAR}, may combine with (inherent) internal (e.g., parasitic) capacitances of transistors M1 and M2 to generate instabilities that may render the amplifier (100) unstable, or in other words, generate conditions for oscillation.

Although operation of the amplifier (100) may be in view of one or more specific (narrow-) frequency bands of operation, in some cases out of band behavior of the amplifier (100) may be considered an important design aspect. In other words, design of the amplifier (100) may be in view of a broadband frequency response of the amplifier (100), including, for example, a requirement/desire to prevent/reduce instabilities/oscillations over the broadband frequency range irrespective of various (even unexpected) input and/or output load conditions.

Teachings according to the present disclosure describe a stability compensation network that targets specific instability frequencies arising from gate inductance at a gate of a cascode transistor of a cascode amplifier.

### SUMMARY

According to a first aspect of the present disclosure, a cascode amplifier is presented, comprising: an input transistor in series connection with a cascode transistor; a gate capacitor coupled between a gate of the cascode transistor and a reference ground; and a stability compensation LC resonator coupled between the gate of the cascode transistor and the reference ground, the stability compensation LC resonator comprising an inductor in series connection with a capacitor, wherein values of the inductor and capacitor of the stability compensation LC resonator are selected to provide an impedance of the stability compensation LC resonator that is substantially equal to zero at a frequency of instability of the cascode amplifier.

According to a second aspect of the present disclosure, a gain boosted cascode amplifier is presented, comprising: an input transistor in series connection with a cascode transistor; a gain boosting inductor coupled between a gate of the cascode transistor and a reference ground; and a stability compensation LC resonator coupled between the gate of the cascode transistor and the reference ground, wherein the gain boosting inductor is configured to increase gain at an in-band frequency of the cascode amplifier, and the stability compensation LC resonator is configured to provide an impedance that is substantially equal to zero at an out of band frequency of instability of the cascode amplifier, the instability caused by an inductance of the gain boosting inductor.

According to a third aspect of the present disclosure, a method for providing unconditional stability to a cascode amplifier is presented, the method comprising: determining an out of band frequency of instability of the cascode amplifier that is based on poles provided by a gate inductance coupled to a gate of a cascode transistor of the cascode amplifier; coupling a stability compensation LC resonator between the gate of the cascode transistor and a reference ground; based on the coupling, shorting the gate of the cascode transistor to the reference ground at the out of band frequency of instability; and further based on the coupling, pushing the poles provided by the gate inductance towards higher frequencies where a gain of the cascode amplifier is sufficiently low, thereby providing unconditional stability to the cascode amplifier.

Further aspects of the disclosure are provided in the description, drawings and claims of the present application.

### BRIEF DESCRIPTION OF THE DRAWINGS

The accompanying drawings, which are incorporated into and constitute a part of this specification, illustrate one or more embodiments of the present disclosure and, together with the description of example embodiments, serve to explain the principles and implementations of the disclosure.

FIG. 1 shows a simplified schematic of a prior art cascode amplifier.

FIG. 2 shows a simplified schematic of a cascode amplifier with a series gate resistor for reducing instabilities.

FIG. 3 shows a simplified schematic of a cascode amplifier according to an embodiment of the present disclosure, including an LC resonator for removing instabilities.

FIG. 4A shows graphs representative of stability performance of the cascode amplifier of FIG. 3.

FIG. 4B shows a zoomed-in region of the graphs of FIG. 4A.

FIG. 5 shows graphs representative of amplifier performance variation provided by the LC resonator according to the present disclosure.

FIG. 6 shows various embodiments according to the present disclosure of the LC resonator of FIG. 3.

FIG. 7A shows a simplified schematic of a cascode amplifier according to an embodiment of the present disclosure, including a gain boosting network and an LC resonator for removing instabilities.

FIG. 7B shows various embodiments according to the present disclosure of the gain boosting network of FIG. 7A.

FIG. 8A shows graphs representative of amplifier gain performance with and without gain boosting.

FIG. 8B shows graphs representative of stability performance versus process variation of the cascode amplifier with gain boosting of FIG. 7A.

FIG. 8C shows graphs representative of gain boost and stability performance of the cascode amplifier of FIG. 7A.

FIG. 9 shows a simplified schematic of a cascode amplifier according to an embodiment of the present disclosure, including an LC resonator for removing instabilities that may be coupled to a cascode transistor of a plurality of cascode transistors of the cascode amplifier.

FIG. 10 shows various process steps of a method according to the present disclosure.

Like reference numbers and designations in the various drawings indicate like elements.

### DETAILED DESCRIPTION

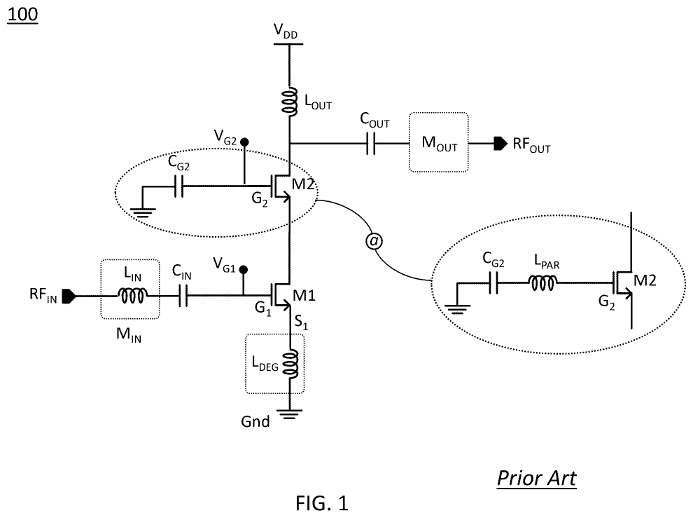

At higher frequencies, presence of the gate inductance, L_{PAR}, in series connection with the gate capacitor, C_{G2}, may render functioning of the prior art amplifier (100) of FIG. 1 similar to a known in the art Colpitts oscillator. In such case, a frequency of oscillation of the Colpitts oscillator may be at a frequency that is greater than the operating frequency of the amplifier (100) and based on a resonance provided by the parallel combination of the gate inductance, L_{PAR}, with (inherent) internal (e.g., parasitic) capacitances of transistors M1 and M2, including, for example, gate-to-source capacitance of M2 in series connection with the drain-to-gate and gate-to-source capacitances of M1.

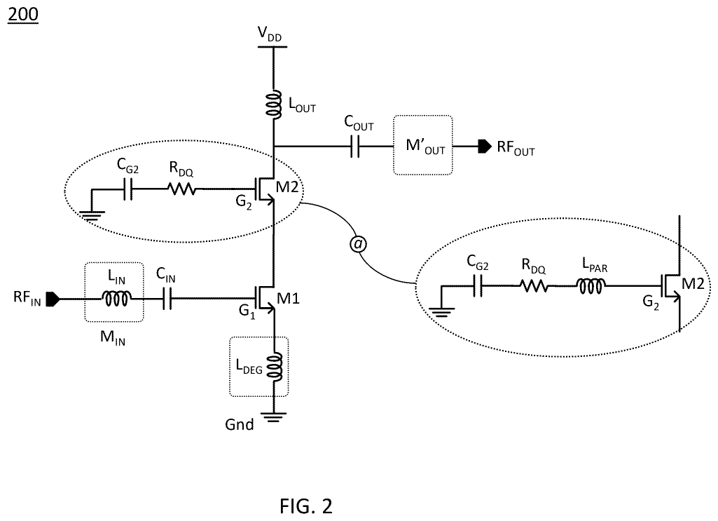

Implementations for reducing instabilities/oscillations caused by the gate inductance, L_{PAR}, (combined with the internal capacitances of M1 and M2) may include energy dissipation at a frequency region of the instabilities/oscillations. One such implementation may include, for example, use of a resistor, R_{DQ}, in series connection with the gate capacitor, C_{G2}, and therefore with the gate inductance, L_{PAR}, as shown in FIG. 2, that is configured to reduce a q-factor of the parallel combination of L_{PAR} with the internal capacitances of M1 and M2. Another such implementation, as shown in FIG. 2, may include, for example, use of a modified (e.g., detuned) output match circuit that is configured to attenuate amplitude components at about the frequency region of instabilities/oscillations.

A drawback for implementations according to FIG. 2 may include degradation in amplifier in-band performances, including, for example, a performance in gain, noise figure, and/or linearity. Furthermore, although such implementations may reduce instabilities/oscillations in some cases or scenarios, they may not provide unconditional stability of the amplifier. As used herein, unconditional stability of an amplifier, including an LNA or a PA, may refer to lack of any frequency of instability of the amplifier over the broadband frequency range (e.g., entire frequency spectrum, including in-band frequency and out of band frequency) irrespective of input and/or output load conditions. Such unconditional stability may therefore allow a chip manufacturer to, for example, ship/sell its product (e.g., amplifier chip/module) to a system integrator for integration within a device while guaranteeing its stability irrespective of input/output loads provided by the integration.

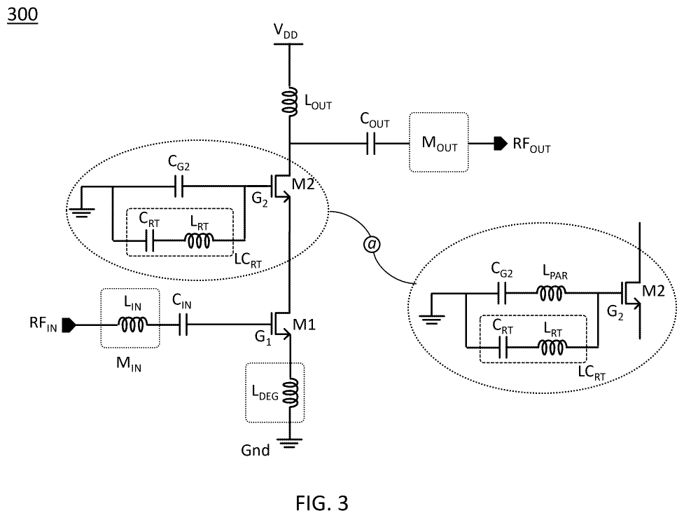

Teachings according to the present disclosure overcome the above-described shortcoming by providing, as shown in the (cascode) amplifier (300) of FIG. 3, a stability compensation network (LC_{RT}, e.g., LC resonator, LC resonator trap, LC trap) that includes a series connection of an inductor, LRT, and a capacitor, CRT, connected between the gate, G₂, of the cascode transistor, M2, and the reference ground, Gnd. In other words, as shown in the detail a of FIG. 3, the LC resonator, LC_{RT}, is coupled in parallel with the parasitic inductor, L_{PAR}, that is in series connection with the gate capacitor, C_{G2}. In other words, the LC resonator, LC_{RT}, may be considered in parallel with the above-described internal capacitances of M1 and M2. It should be noted that although use of the stability compensation network (LC resonator), LC_{RT}, according to the present disclosure may render presence of the resistor, R_{DQ}, shown in FIG. 2 unnecessary, teachings according to the present disclosure may however be compatible with concurrent use of the stability compensation network, LC_{RT}, and the resistor, R_{DQ}.

The stability compensation network, LC_{RT}, according to the present disclosure may include a resonant frequency at a frequency that is equal to, or substantially equal to, a frequency of instability of the cascode amplifier. The stability compensation network, LC_{RT}, according to the present disclosure pushes poles of a resonant circuit coupled to the gate, G₂, of the cascode transistor, M2, further away in the frequency spectrum (i.e., towards higher frequencies in the out of band frequency spectrum of the cascode amplifier) and in a region where the cascode amplifier (e.g., equivalent Colpitts oscillator) has a gain that is sufficiently low not to excite/amplify instabilities provided at those poles. Accordingly, the stability compensation network, LC_{RT}, according to the present disclosure may create an RF short at the frequency of instability of the cascode amplifier, thereby effectively shorting the gate, G₂, to the reference ground, Gnd, at the frequency of instability.

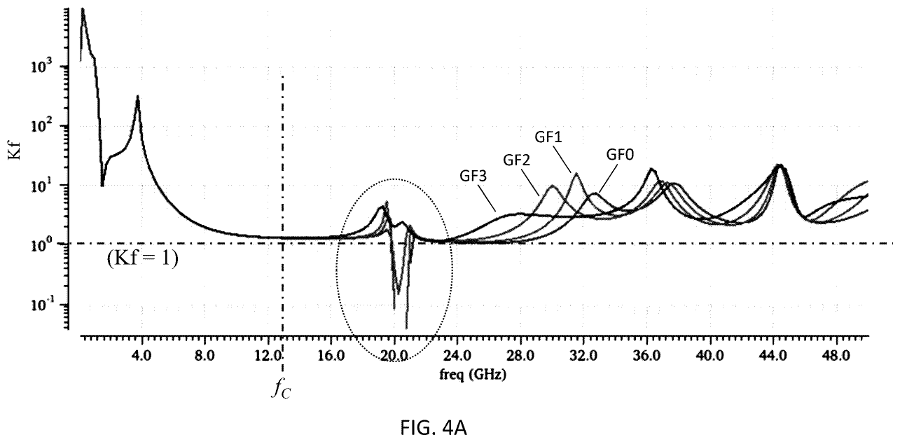

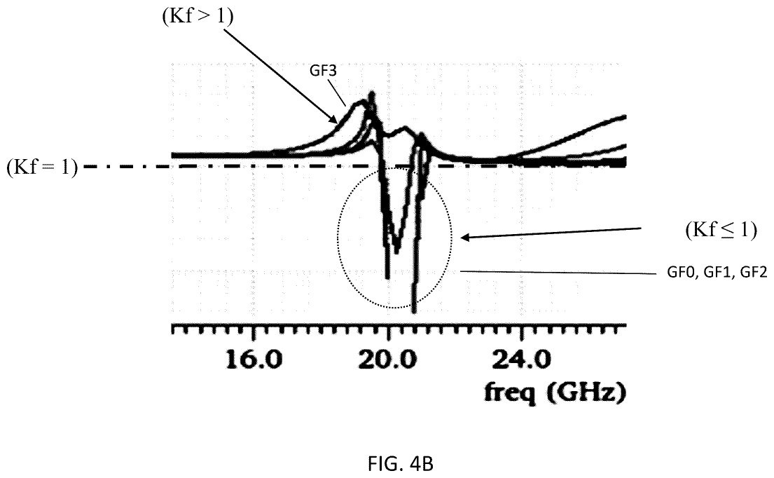

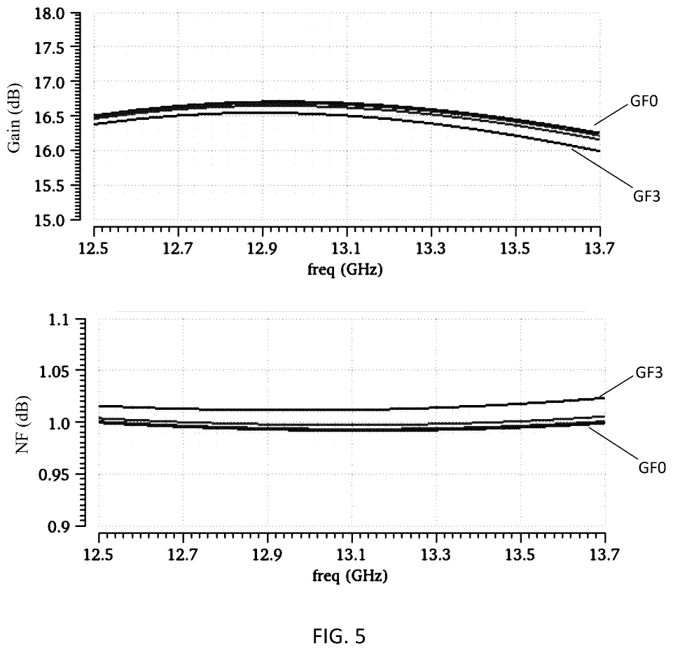

With continued reference to FIG. 3, the stability compensation network, LC_{RT}, according to the present disclosure may be designed to target a specific frequency of instability that may be higher than a frequency of operation (e.g., in-band frequency of operation, center frequency of operation) of the cascode amplifier (300). Accordingly, and as shown in graphs of FIG. 4 and FIG. 5 (later described), the instabilities may be eliminated with minimal or reduced effect in the in-band (RF) performance of the LNA.

According to an embodiment of the present disclosure, a frequency of instability targeted by the stability compensation network, LC_{RT}, of the cascode amplifier (300) may be (first) determined via simulation programs/routines that consider a circuital layout and component values of the cascode amplifier (300) without considering presence of the stability compensation network (e.g., LC_{RT}). In other words, a frequency of instability may be first determined based on the inherent resonant circuit (i.e., L_{PAR} in parallel combination with internal capacitances of M1 and M2) of the configuration (100) of FIG. 1, following which component values (e.g., L_{RT}, C_{RT}) of the stability compensation network (e.g., LC_{RT}) that target the frequency of instability may be determined. Subsequently, same simulation programs may be used to verify lack of any frequency of instability (e.g., unconditional stability) for the combined circuital layout, i.e., the cascode amplifier (300). Furthermore, based on the verification, and if any frequency of instability remains (i.e., for the combined circuital layout, cascode amplifier 300), more/successive iterations of the determining of the component values (e.g., converging) followed by the verification may be performed till the component values convergence to provide unconditional stability of the cascode amplifier (300).

According to an embodiment of the present disclosure, determination of the frequencies of instability of a two-port network/circuit, such as the cascode amplifier (100) of FIG. 1A or (300) of FIG. 3, may include assessing (a magnitude of) the known in the art k-factor (or μ-factor) of the two-port network/circuit. As known to a person skilled in the art, the k-factor (or μ-factor) of the two-port network/circuit, such as the cascode amplifier (100/300), may be used to determine stability criteria of the two-port network/circuit based on corresponding (well known in the art) scattering parameters (i.e., S₁₁, S₁₂, S₂₁, S₂₂). Not only the k-factor (or μ-factor) can be used as a test for unconditional stability (i.e., magnitude strictly greater than 1, i.e., |k-factor|>1 or |μ-factor|>1), but also a magnitude of such factor can be used to determine an available margin of the unconditional stability. In other words, the greater the distance of the magnitude of the k- or μ-factor from 1, the stronger/more robust the unconditional stability.

It should be noted that teachings according to the present disclosure may not be limited to use of the k- or μ-factor for determining (unconditional) stability of an amplifier. Other methods for determination (and verification) of a frequency of instability may include, for example, testing of a broadband frequency response of an actual circuital implementation of the amplifier and identifying frequencies of instability via presence of corresponding oscillations. A person skilled in the art may know of other methods for determination (and verification) of the frequencies of instability of an amplifier, all of which may be considered compatible with determination/derivation of the stability compensation network (e.g., LC_{RT}) according to the present teachings.

Once a frequency of instability is determined, then values of the components (L_{RT}, C_{RT}) of the stability compensation network, LC_{RT}, may be derived (and iteratively optimized) in view of such frequency of instability and in further view of a frequency range of operation of the (cascode) amplifier. It should be noted that a sequence in the series connection of the components (L_{RT}, C_{RT}) may not substantially affect the coupling effect of the stability compensation network, LC_{RT}, over the cascode amplifier (e.g., gate of the cascode transistor M2), and therefore, teachings according to the present disclosure may equally apply to any of two possible sequences in the series connection.

With reference back to FIG. 3, according to an embodiment of the present disclosure, values (e.g., L and C) of the components (L_{RT}, C_{RT}) of the compensation network, LC_{RT}, may be selected so that a resonant frequency (e.g., proportional to LC^{-1/2}) of the combined LC resonator tank (e.g., L_{PAR} in parallel with internal capacitances of M1 and M2 and further in parallel with LC_{RT}) may be sufficiently distant from the frequency of operation of the cascode amplifier. According to an embodiment of the present disclosure, such component values may be selected so that the resonant frequency of the combined LC resonator tank (e.g., L_{PAR} in parallel with internal capacitances of M1 and M2 and further in parallel with LC_{RT}) may be at a frequency that is equal to, or greater than, about one and a half times (e.g., 1.5×) the (center) frequency of operation of the cascode amplifier (300). Such choice of component values may naturally provide an impedance of the combined LC resonator tank (coupled to the gate G₂) that is substantially equal to zero (i.e., short) at the (center) frequency of operation of the cascode amplifier (300). It should be noted that because a capacitance of the gate capacitor, C_{G2}, is by design selected to provide a short at the frequencies of operation of amplifier, such gate capacitor may also be likened to a short at higher frequencies and therefore have reduced effect on the overall gain/phase response of the combined LC resonator tank (e.g., L_{PAR} in parallel with internal capacitances of M1 and M2 and further in parallel with LC_{RT}). In other words, at higher frequencies, the combined LC resonator tank may be likened to the gate parasitic inductance, L_{PAR}, in parallel with the stability compensation network, LC_{RT}, which is further in parallel with internal capacitances of M1 and M2.

With further reference to FIG. 3, according to an embodiment of the present disclosure, a value of the inductor, L_{RT}, of the stability compensation network, LC_{RT}, may be selected to be in a range from about 20 pH (picohenries) to about 1000 pH. According to an embodiment of the present disclosure, a value capacitor, C_{RT}, of the stability compensation network, LC_{RT}, may be selected to be in a range from about 20 fF (femtofarads, i.e., picofarads⁻³) to about 300 fF. Such ranges for values of L_{RT} and C_{RT} may represent typical ranges of values of the inductor, L_{RT}, and capacitor, C_{RT}, for provision of unconditional stability of an amplifier operating in the frequency range from about 1 GHz to about 100 GHz.

According to an embodiment of the present disclosure, optimization, or tuning, of the values of the inductor and capacitor, L_{RT} and C_{RT}, of the stability compensation network, LC_{RT}, may be provided by, for example, first establishing/selecting a value of the inductor, L_{RT}, and then running a stability optimization routine by scanning for different values of the capacitor, C_{RT}, and checking stability performance for each of the scanned values. Graphs representative of such stability optimization routine are shown in FIGS. 4A/4B.

FIG. 4A shows graphs representative of stability performance of the cascode amplifier of FIG. 3 for different values of the capacitor, C_{RT}, and a preselected value (e.g., constant, fixed) of the inductor, L_{RT}, of the stability compensation network, LC_{RT}. In the exemplary case represented by the graphs of FIG. 4A, the cascode amplifier (300) may operate at a (center) frequency (labelled as f_{C}) of about 13 GHz and the inductor, L_{RT}, may be preselected to be equal to about 150 pH. Accordingly, FIG. 4A shows fours graphs (GF0, GF1, GF2, GF3) representative of the k-factor (labelled as Kf) of the amplifier (300) versus frequency (labelled as freq in GHz) for exemplary values of the capacitor, C_{RT}, equal to (0, 18.5, 37, 75) femtofarads respectively. Also shown in FIG. 4A is the Kf=1 reference line that may be used to establish a condition (i.e., Kf>1) sufficient for stability of the cascode amplifier (300).

As shown in FIG. 4A, a frequency of instability exists in a region about the frequency of 20 GHz. When zooming in in that region, as shown in FIG. 4B, it becomes apparent that graphs GF0, GF1 and GF2 include excursions of the k-factor below the value of one (i.e., Kf=1 reference line) which indicate possible instability of the cascode amplifier (300) at the frequency range of about 20 GHz. On the other hand, graph GF3 does not include any values of the k-factor that is below (or equal to) to one. Accordingly, GF3, may represent a configuration of an amplifier having unconditional stability.

As further shown in FIG. 4A, in a (narrow) frequency band of operation (e.g., in-band) of the amplifier (300) that is centered at f_{C}=13 GHz, no substantial difference in the k-factor, and therefore in the scattering parameters (e.g., s-parameters) of the amplifier (300) may be observed. Accordingly, as shown in the graphs of FIG. 5, no substantial (e.g., insignificant) degradation of the gain (top graph, Gain) and noise figure (bottom graph, NF) of the amplifier (300) may be observed, including for the unconditionally stable configuration represented by the graph GF3. It should be noted that graph GF0 of FIGS. 4A/4B/5 is representative of a capacitor, C_{RT}, having a value of zero (e.g., open circuit and therefore the graph GF0 may be representative of performances (e.g., k-factor, gain, noise figure) of the prior art configuration shown in FIG. 1 (e.g., devoid of LC_{RT}).

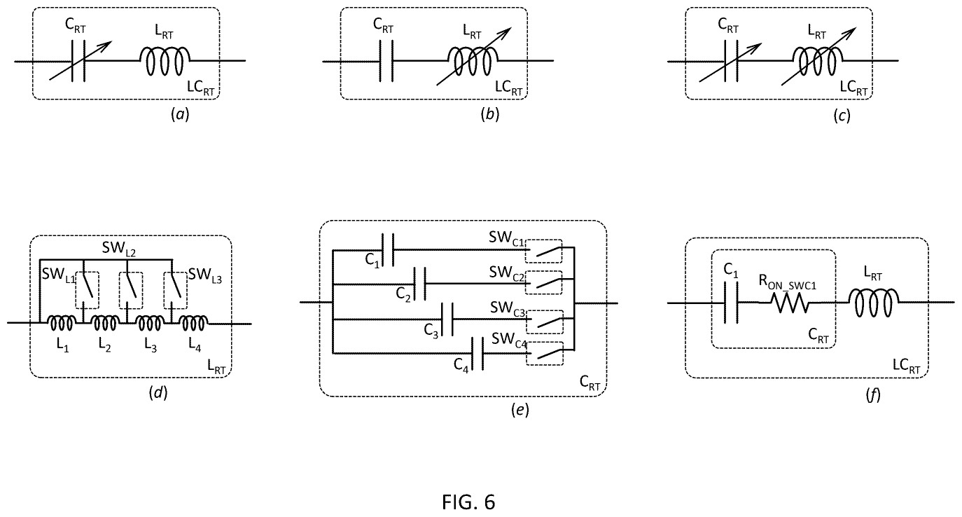

FIG. 6 shows various embodiments according to the present disclosure of the stability compensation network, LC_{RT}, described above with reference to FIG. 3. In particular, as shown in the configurations (a), (b), and (c) of FIG. 6, the stability compensation network, LC_{RT}, may be an LC resonator, LC_{RT}, with any one or both of the inductor, L_{RT}, and the capacitor, C_{RT}, having respective switchable (e.g., tunable, variable, adjustable, selectable) inductance and/or capacitance. Such tuning of the inductor, L_{RT}, and/or the capacitor, C_{RT}, may in turn provide tunability of the stability compensation network, LC_{RT}, according to the present teachings.

According to an embodiment of the present disclosure such tunability may be used to optimize a response of the stability compensation network, LC_{RT}, for provision of unconditional stability in view of a single frequency (band) of instability as described above with reference to FIGS. 4A/4B. According to an embodiment of the present disclosure, once an optimized response of the stability compensation network, LC_{RT}, is established, corresponding values of the switchable inductor, L_{RT}, and/or capacitor, C_{RT}, may be stored in a lookup table for use/retrieval during operation of the cascode amplifier (300). According to an embodiment of the present disclosure, an optimized response of the stability compensation network, LC_{RT}, may be established for any one of a plurality of different modes of operation (e.g., frequency bands of operation, gains, or other) of the cascode amplifier (300), and corresponding (mode-specific) values of the switchable inductor, L_{RT}, and/or capacitor, C_{RT}, may be stored in a lookup table for use/retrieval during operation of the cascode amplifier (300) according to any one of the modes of operation. Alternatively, such values may be fused into the switchable inductor, L_{RT}, and/or capacitor, C_{RT}, so to force the same value irrespective of any control words to the switchable inductor and/or capacitor.

According to an embodiment of the present disclosure such tunability may be used to optimize a response of the stability compensation network, LC_{RT}, for provision of unconditional stability in view of a plurality of frequencies (e.g., bands) of instabilities that may correspond to a plurality of modes of operation of the amplifier (300). Such modes of operation may represent, for example, different gain settings and/or different (frequency) bands of operation of the amplifier (300). It should be noted that provision of the different modes of operation may further be provided via adjusting/tuning of other elements of the amplifier, including, for example, levels of DC biasing voltages (e.g., V_{G1}, V_{G2}) and/or input/output matching (e.g., M_{IN}, L_{DEG}, M_{OUT}). It should further be noted that description of a biasing circuit that generate biasing voltages (e.g., V_{G1}, V_{G2} of FIG. 1) to gates of a cascode amplifier is beyond the scope of the present disclosure. As known to a person skilled in the art, such biasing voltages may be coupled to the gates (e.g., G₁, G₂) of transistors of cascode amplifier through reactive and/or resistive elements/networks of the biasing circuit that are configured to only pass low frequencies in the DC range/domain and not in the RF range/domain. In other words, such reactive and/or resistive elements/networks of the biasing circuit may not be likened to the stability compensation network, LC_{RT}, of the present teachings.

As shown in the configuration (d) of FIG. 6, an exemplary tunable inductor, L_{RT}, may be provided by a plurality of series-connected inductors (e.g., L₁, L₂, L₃, L₄) and a plurality of switches (e.g., SW_{L1}, SW_{L2}, SW_{L3}) configured to short one or more of the inductors, thereby effectively removing the one or more (shorted) inductors from affecting a combined inductance of the (switchable) inductor, L_{RT}. For example, the combined inductance may be respectively provided by the inductance(s) of: (L₁, L₂, L₃, L₄) when all switches are open; (L₂, L₃, L₄) when switch SW_{L1} is closed and all other open; (L₃, L₄) when switch SW_{L2} is closed and switch SW_{L3} is open (and irrespective of a state of the switch SW_{L1}); and L₄ when switch SW_{L3} is closed (and irrespective of states of the switches SW_{L1} and SW_{L2}). Same structure of a plurality of series connected reactances (e.g., inductors or capacitors) may be used for provision of a tunable capacitor, e.g., C_{RT}.

As shown in the configuration (e) of FIG. 6, an exemplary tunable capacitor, C_{RT}, may be provided by a plurality of (independently selectable) parallel connected capacitors (e.g., C₁, C₂, C₃, C₄), each capacitor in series connection with a respective switch of a plurality of switches (e.g., SW_{C1}, SW_{C2}, SW_{C3}, SW_{C4}). Accordingly, closing or opening a switch of the plurality of switches (e.g., SW_{C1}, SW_{C2}, SW_{C3}, SW_{C4}) may include or exclude a capacitance of the respective capacitor (e.g., C₁, C₂, C₃, C₄) to/from the tunable capacitor, C_{RT}. Same structure of a plurality of parallel connected reactances (e.g., inductors or capacitors) may be used for provision of a tunable inductor, e.g., L_{RT}.

According to an embodiment of the present disclosure, an ON-resistance of the switches (e.g., SW_{L1}, . . . , SW_{C1}, . . . ) used for provision of the tunable capacitor, C_{RT}, (or tunable inductor, L_{RT}) as described with reference to configurations (d) and (e) of FIG. 6, may be used to reduce a q-factor of the LC resonator, LC_{RT}. In other words, as shown in the configuration (f) of FIG. 6, a size (e.g., width and/or length) of a transistor used to implement each of the switches (e.g., SW_{C1}) may be selected to provide a desired ON-resistance (e.g., R_{ON_SWC1}) that when combined in series with a capacitance (e.g., C₁) the capacitor, C_{RT}, reduces the q-factor of the LC resonator, LC_{RT}, and therefore may widen a frequency band affected by the coupling of the LC resonator, LC_{RT}, to the gate of the cascode transistor, M2. Such widening may advantageously be used to cover/compensate/target an entirety of a frequency region of the instability (e.g., as shown in the encircled region of FIG. 4B). In other words, the ON-resistance, R_{ON_SWC1}, of the switch may widen a bandwidth of the LC resonator, LC_{RT}, about its resonant frequency to match or encompass a bandwidth of the instability.

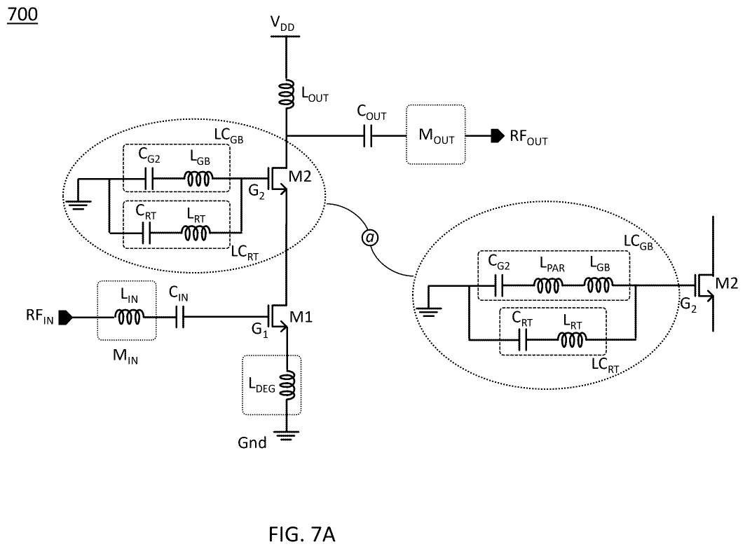

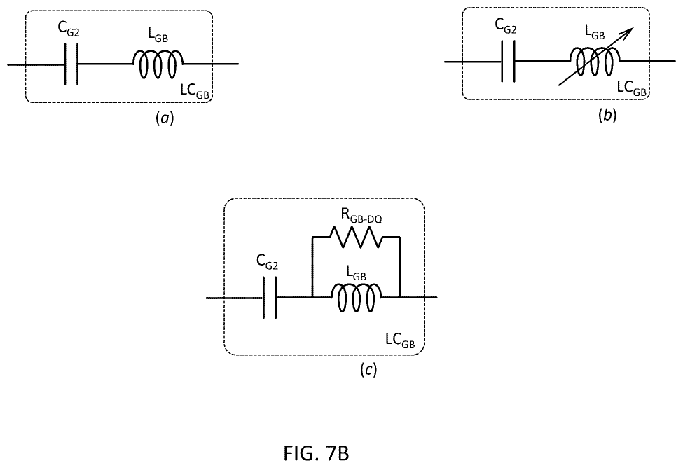

Based on the above description with reference to FIGS. 3-6, it is shown that the stability compensation network, LC_{RT}, according to the present disclosure may be used to compensate, or in other words, remove, instabilities produced by a gate inductance (e.g., L_{PAR}) that is coupled to a gate of a cascode transistor (e.g., M2) of a cascode amplifier (e.g., 300). In the particular case described with reference to, e.g., FIG. 3, the stability compensation network, LC_{RT}, is used to remove instabilities caused by a parasitic gate inductance, L_{PAR}, that is inherent to the circuit design and layout. Teachings according to the present disclosure may be extended to compensate for any gate inductance coupled to the gate of a cascode transistor (e.g., M2) of a cascode amplifier. Such extension may include compensation vis-a-vis a gate inductance that as shown in FIG. 7A may be used to provide a gain boost (i.e., increase in gain) for a cascode amplifier (700).

FIG. 7A shows a simplified schematic of a cascode amplifier (700) according to an embodiment of the present disclosure, including a gain boosting network (LC_{GB}, e.g., LC resonator) arranged in parallel with the stability compensation network, LC_{RT}. Gain boosting, or in other words, an in-band gain emphasis, for the cascode amplifier (700) may be provided via a (gain boosting) gate inductor, L_{GB}, that is arranged in series connection with the gate capacitor, C_{G2}, to provide the gain boosting network, LC_{GB}. As shown in the detail a of FIG. 7A, and due to the inherent presence of the parasitic inductor, L_{PAR}, an effective inductance of the gain boosting network, LC_{GB}, may be provided by a sum of the inductances of L_{PAR} and L_{GB}. It should be noted that the gate capacitor, C_{G2}, may not contribute to the gain boosting per se, and remains a short at the frequency of operation of the cascode amplifier (700).

On the other hand, higher order poles generated by presence of the (gain boosting) gate inductor, L_{GB}, in combination with the parasitic gate inductance may generate higher frequency instabilities outside the frequency range of operation of the cascode amplifier (700). Similarly to the configuration described above with reference to FIG. 3, such higher frequency instabilities may be compensated for, and potentially removed, via the stability compensation network, LC_{RT}, that as shown in FIG. 7A, is arranged in parallel with the gain boosting LC resonator, LC_{GB}. Accordingly, the stability compensation network, LC_{RT}, may provide unconditional stability to the gain boosted cascode amplifier (700) by pushing the higher order poles further away in the frequency spectrum (i.e., towards higher frequencies) and in a region where the cascode amplifier (e.g., equivalent Colpitts oscillator formed in combination with internal capacitances of M1 and M2) has a gain that is sufficiently low not to excite/amplify instabilities provided at those poles. Accordingly, the stability compensation network, LC_{RT}, according to the present disclosure may create an RF short at the frequency of instability of the cascode amplifier, thereby effectively shorting the gate, G₂, to the reference ground, Gnd, at the frequency of instability while maintaining a desired in-band performance of the cascode amplifier substantially unaffected.

FIG. 7B shows various embodiments according to the present disclosure of the gain boosting network, LC_{GB}, described above with reference to FIG. 7A. In particular, as shown in FIG. 7B, the gain boosting network, LC_{GB}, may include an inductor, L_{GB}, having a fixed inductance as shown in the configuration (a) of FIG. 7B, or a switchable (e.g., tunable, variable, adjustable, selectable) inductance as shown in the configuration (b) of FIG. 7B. Tuning of the inductor, L_{GB}, as provided for example by the configuration (b) of FIG. 7B, may in turn provide tunability of the gain boosting network, LC_{GB}, according to the present teachings, to provide, for example, different gain boosting associated to different modes of operations of the cascode amplifier (700). As tunability of the gain boosting network, LC_{GB}, may generate instabilities at different frequencies, compensation for such different frequencies for provision of unconditional stability may be provided via any one of the stability compensation network configurations described above with reference to FIG. 6.

According to an embodiment of the present disclosure as shown in the configuration (c) of FIG. 7B, a resistor, R_{GB-DQ}, may be arranged in parallel with the (gain boosting) gate inductor, L_{GB}, to reduce the q-factor of the inductor. The resistor, R_{GB-DQ}, may accordingly widen a frequency range/band of operation affected by the coupling of the inductor, L_{GB}, to the gate of the cascode transistor, M2. Such widening may advantageously be used to cover/target an entirety of a frequency region (e.g., bandwidth) of a band of operation of the cascode amplifier (700). Such widening may in turn affect a frequency width of a corresponding instability which may be matched/compensated via, e.g., the above-described configuration (f) of FIG. 6. It should be noted that the resistor, R_{GB-DQ}, may be included in any one of the configurations (a) or (b) of FIG. 7B and may optionally be a tunable (e.g., variable, adjustable, selectable, switchable) resistor.

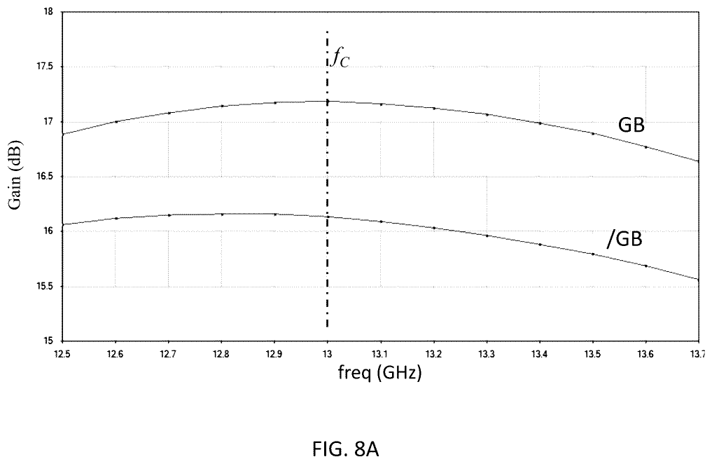

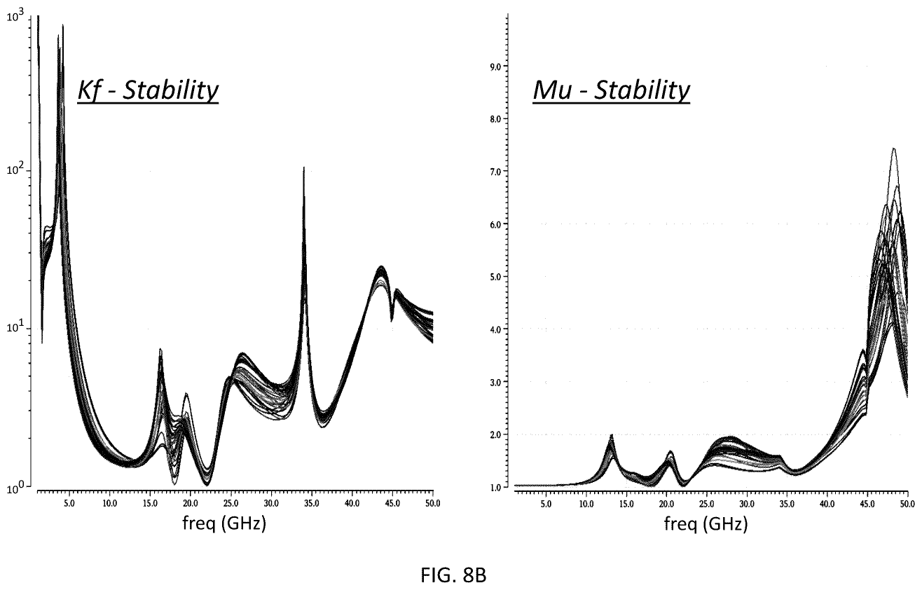

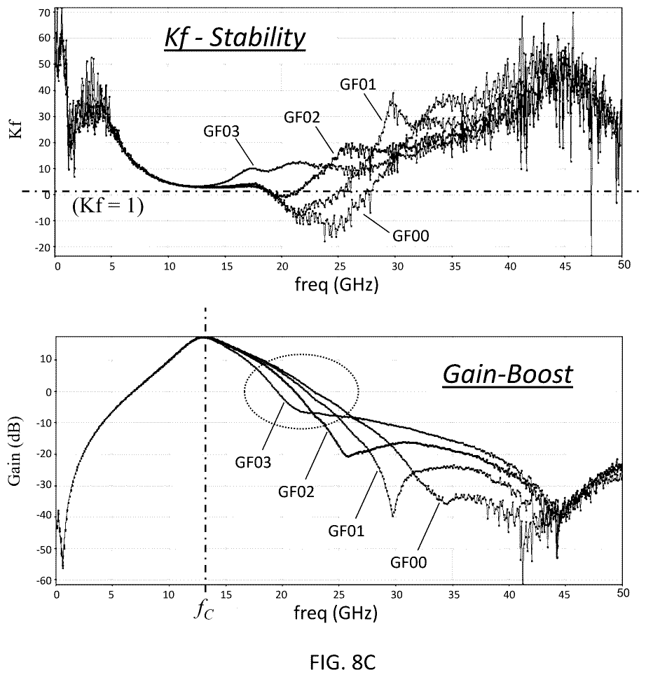

FIG. 8A shows graphs representative of gain performance of a cascode amplifier according to the present disclosure with (labelled as GB, e.g., 700 of FIG. 7A) and without (labelled as/GB, e.g., 300 of FIG. 3) gain boosting LC resonator, LC_{GB}. As shown in FIG. 8A, at about the center frequency, f_{C}, of 13 GHZ, a gain boost (e.g., added gain) of about 1.1 dB may be provided by the gain boosting LC resonator, LC_{GB}, of FIG. 7A when compared to no gain boost (e.g., configuration of FIG. 3). Furthermore, as shown in the graphs of FIG. 8B, gain boost may be provided while maintaining unconditional stability (i.e., according to k-factor and μ-factor) as provided by the LC resonator, LC_{RT}.

FIG. 8B shows left and right figures, each including graphs representative of stability performance according to k-factor (left figure) and μ-factor (right figure) versus PVT (process, voltage, temperature) variation of the cascode amplifier (700) with gain boosting of FIG. 7A. As shown in FIG. 8B, unconditional stability (i.e., |k-factor|>1 or |μ-factor|>1) is preserved over PVT variation as provided by 3×3×3=27 different PVT points/graphs for each of the left and right figures. These PVT points represent three different process fabrication points of the cascode amplifier (700), three different levels of the supply voltage (e.g., V_{DD} of FIG. 7A) to the cascode amplifier (700), and three different operating temperatures of the cascode amplifier (700). Accordingly, the graphs shown in FIG. 8B showcase robustness/effectiveness of the LC resonator, LC_{RT}, according to the present disclosure for provision of unconditional stability even for a case of higher values gate inductance (e.g., L_{GB} of FIG. 7A) as required by the gain boosting network (e.g., LC_{GB}, of FIG. 7A). Such robustness in turn translates to a viable product that may operate in the field as intended. It is noted that vertical axis graduation for both of the left and right graphs of FIG. 8B start at the value of one (i.e., k-factor=10⁰ and μ-factor=1).

FIG. 8C shows graphs representative of measured stability (top graphs) and measured gain boost (bottom graphs) performance of the cascode amplifier (700) of FIG. 7A for different values of the capacitor, C_{RT}, and a preselected value (e.g., constant, fixed) of the inductor, L_{RT}, of the stability compensation network, LC_{RT}. In the exemplary case represented by the graphs of FIG. 8C, the cascode amplifier (700) may operate at a (center) frequency (labelled as f_{C}) of about 13 GHz. Shown in the top region of FIG. 8C, are fours Kf-Stability graphs (GF00, GF01, GF02, GF03) representative of the k-factor (labelled as Kf) of the amplifier (700) versus frequency (labelled as freq in GHz) for different increasing values of the capacitor, C_{RT}, in a range from about 20 fF to about 150 fF. Also shown in the top region of FIG. 8C is the Kf=1 reference line that may be used to establish a condition (i.e., Kf>1) sufficient for stability of the cascode amplifier (700).

As shown in the Kf-Stability graphs of FIG. 8C, for the highest value of the capacitor, C_{RT}, as represented by the measured stability data (k-factor) of graph, GF03, the cascode amplifier (700) is unconditionally stable. On the other hand, for other (and therefore smaller) values of the capacitor, C_{RT}, as represented by the measured stability data (k-factor) of graphs, GF00-GF02, frequencies of instability exist in a frequency region from about 20 GHz to about 28 GHz, with varying degrees of instability (e.g., based on length of corresponding excursions below the Kf=1 reference line).

Shown in the bottom region of FIG. 8C, are four Gain-Boost graphs representative of an effect of the different values of the capacitor, C_{RT}, on a measured gain (e.g., labelled as Gain Boost in FIG. 8C) of the cascode amplifier (700). As shown in the Gain-Boost graphs of FIG. 8C, the different values of the capacitor, C_{RT}, do not substantially affect in-band (i.e., about the center frequency fc) gain of the cascode amplifier (700). On the other hand, as shown in the encircled region of the Gain-Boost graphs of FIG. 8C, the different values of the capacitor, C_{RT}, do affect out of band gain, or in other words, out of band rejection performance of the cascode amplifier (700). A person skilled in the art would appreciate such performance enhancement provided by the stability compensation network, LC_{RT}, according to the present teachings when used in the gain boosted cascode amplifier (700) described above with reference to FIG. 7A. Not only higher values of the capacitor, C_{RT}, may be used to provide unconditional stability as shown in the Kf-Stability graphs of FIG. 8C, but such higher values may be further and advantageously used to control/enhance an out of band rejection performance of the gain boosted cascode amplifier (700).

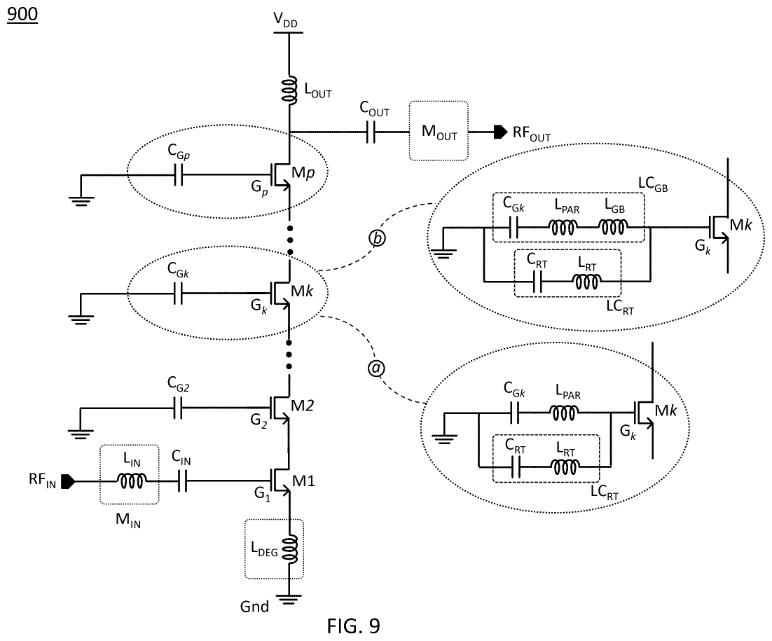

Although in the above description the cascode amplifier is described as including one cascode transistor (i.e., M2, output cascode transistor), a person in the art is well aware that cascode amplifiers with more than one cascode transistor are possible. For example, FIG. 9 shows a cascode amplifier (900) with (p−1) cascode transistors (M2, . . . , Mk, . . . . Mp) where p may be any integer number equal to, or greater than, two (i.e., p≥2). In such cascode amplifier (900), respective gate capacitors (C_{G2}, . . . , C_{Gk}, . . . , C_{Gp}) are coupled to gates (G₂, . . . , Gₖ, . . . , Gₚ) of the cascode transistors (M2, . . . , Mk, . . . . Mp). The gate capacitors (C_{G2}, . . . , C_{Gk}, . . . , C_{Gp}) are configured to shunt the respective gates to the reference ground, Gnd, at the frequency (band) of operation of the amplifier (900). As represented by details a and b of FIG. 9, teachings according to the present disclosure may equally apply to cascode amplifiers (e.g., LNA, PA) that include more than one cascode transistor, including two, three, four or more cascode transistors that are in series connection with one another. Furthermore, teachings according to the present disclosure may not be limited to LNA's based on cascode configurations, rather, the present teachings may equally apply to an LNA configuration comprising a single (input/output) transistor, and therefore devoid of a cascode transistor.

As shown in detail a of FIG. 9, the stability compensation network, LC_{RT}, according to the present teachings may be coupled to a gate of any cascode transistor, Mk, of the cascode amplifier (900), so to compensate (e.g., remove) any instabilities caused by a corresponding parasitic gate inductance, L_{PAR}. According to an exemplary embodiment of the present disclosure, the stability compensation network, LC_{RT}, may be coupled (according to detail a) to the gate of the output cascode transistor (i.e., k=p) to remove instabilities caused by parasitic gate inductance, thereby providing unconditional stability for the cascode amplifier (900).

Furthermore, as shown in detail b of FIG. 9, gain boosting for the cascode amplifier (900) may be provided by coupling the gain boosting network, LC_{GB}, according to the present disclosure, to any one or more of the cascode transistors (M2, . . . , Mk, . . . . Mp). In such configuration, a (companion) stability compensation network, LC_{RT}, may be coupled to the gate of the same cascode transistor in order to compensate for instabilities generated by the inductance of the gain boosting network, LC_{GB}.

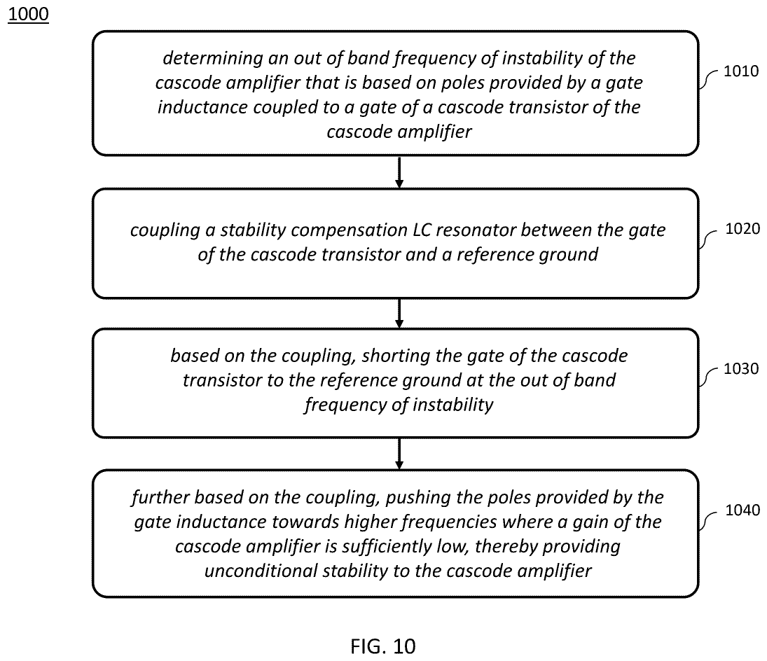

FIG. 10 is a process chart (1000) showing various steps of a method according to the present disclosure for providing unconditional stability to a cascode amplifier. As shown in FIG. 10, such steps include: determining an out of band frequency of instability of the cascode amplifier that is based on poles provided by a gate inductance coupled to a gate of a cascode transistor of the cascode amplifier, according to step (1010); coupling a stability compensation LC resonator between the gate of the cascode transistor and a reference ground, according to step (1020); based on the coupling, shorting the gate of the cascode transistor to the reference ground at the out of band frequency of instability, according to step (1030); and further based on the coupling, pushing the poles provided by the gate inductance towards higher frequencies where a gain of the cascode amplifier is sufficiently low, thereby providing unconditional stability to the cascode amplifier, according to step (1040).

Applications that may include the novel apparatus and systems of various embodiments include electronic circuitry used in high-speed computers, communication and signal processing circuitry, modems, single or multi-processor modules, single or multiple embedded processors, data switches, and application-specific modules, including multilayer, multi-chip modules. Such apparatus and systems may further be included as sub-components within a variety of electronic systems, such as televisions, cellular telephones, personal computers (e.g., laptop computers, desktop computers, handheld computers, tablet computers, etc.), workstations, radios, video players, audio players (e.g., mp3 players), vehicles, medical devices (e.g., heart monitor, blood pressure monitor, etc.) and others. Some embodiments may include a number of methods.

The term “MOSFET” technically refers to metal-oxide-semiconductor-field-effect-transistors; another synonym for MOSFET is “MISFET”, for metal-insulator-semiconductor FET. However, “MOSFET” has become a common label for most types of insulated-gate FETs (“IGFETs”). Despite that, it is well known that the term “metal” in the names MOSFET and MISFET is now often a misnomer because the previously metal gate material is now often a layer of polysilicon (polycrystalline silicon). Similarly, the “oxide” in the name MOSFET can be a misnomer, as different dielectric materials are used with the aim of obtaining strong channels with smaller applied voltages. Accordingly, the term “MOSFET” as used herein is not to be read as literally limited to metal-oxide-semiconductor FETs, but instead includes IGFETs in general.

As should be readily apparent to one of ordinary skill in the art, various embodiments of the invention can be implemented to meet a wide variety of specifications. Unless otherwise noted above, selection of suitable component values is a matter of design choice and various embodiments of the invention may be implemented in any suitable IC technology (including but not limited to MOSFET and IGFET structures), or in hybrid or discrete circuit forms. Integrated circuit embodiments may be fabricated using any suitable substrates and processes, including but not limited to standard bulk silicon, silicon-on-insulator (SOI), silicon-on-sapphire (SOS), GaN HEMT, GaAs pHEMT, and MESFET technologies. However, the inventive concepts described above are particularly useful with an SOI-based fabrication process (including SOS), and with fabrication processes having similar characteristics. Fabrication in CMOS on SOI or SOS enables low power consumption, the ability to withstand high power signals during operation due to FET stacking, good linearity, and high frequency operation (in excess of about 10 GHz, and particularly above about 20 GHz). Monolithic IC implementation is particularly useful since parasitic capacitances generally can be kept low (or at a minimum, kept uniform across all units, permitting them to be compensated) by careful design.

Voltage levels may be adjusted or voltage and/or logic signal polarities reversed depending on a particular specification and/or implementing technology (e.g., NMOS, PMOS, or CMOS, and enhancement mode or depletion mode transistor devices). Component voltage, current, and power handling capabilities may be adapted as needed, for example, by adjusting device sizes, serially “stacking” components (particularly FETs) to withstand greater voltages, and/or using multiple components in parallel to handle greater currents. Additional circuit components may be added to enhance the capabilities of the disclosed circuits and/or to provide additional functions without significantly altering the functionality of the disclosed circuits.

The examples set forth above are provided to give those of ordinary skill in the art a complete disclosure and description of how to make and use the embodiments of the gate drivers for stacked transistor amplifiers of the disclosure and are not intended to limit the scope of what the applicant considers to be the invention. Such embodiments may be, for example, used within mobile handsets for current communication systems (e.g., WCDMA, LTE, WiFi, etc.) wherein amplification of signals with frequency content of above 100 MHz and at power levels of above 50 mW may be required. The skilled person may find other suitable implementations of the presented embodiments.

Modifications of the above-described modes for carrying out the methods and systems herein disclosed that are obvious to persons of skill in the art are intended to be within the scope of the following claims. All patents and publications mentioned in the specification are indicative of the levels of skill of those skilled in the art to which the disclosure pertains. All references cited in this disclosure are incorporated by reference to the same extent as if each reference had been incorporated by reference in its entirety individually.

It is to be understood that the disclosure is not limited to particular methods or systems, which can, of course, vary. It is also to be understood that the terminology used herein is for the purpose of describing particular embodiments only and is not intended to be limiting. As used in this specification and the appended claims, the singular forms “a”, “an”, and “the” include plural referents unless the content clearly dictates otherwise. The term “plurality” includes two or more referents unless the content clearly dictates otherwise. Unless defined otherwise, all technical and scientific terms used herein have the same meaning as commonly understood by one of ordinary skill in the art to which the disclosure pertains.

A number of embodiments of the disclosure have been described. Nevertheless, it will be understood that various modifications can be made without departing from the spirit and scope of the present disclosure. Accordingly, other embodiments are within the scope of the following claims.

1. A cascode amplifier, comprising:
an input transistor in series connection with a cascode transistor;
a gate capacitor coupled between a gate of the cascode transistor and a reference ground; and
a stability compensation LC resonator coupled between the gate of the cascode transistor and the reference ground, the stability compensation LC resonator comprising an inductor in series connection with a capacitor,
wherein values of the inductor and capacitor of the stability compensation LC resonator are selected to provide an impedance of the stability compensation LC resonator that is substantially equal to zero at a frequency of instability of the cascode amplifier.

2. The cascode amplifier of claim 1, wherein:
the stability compensation LC resonator is configured to provide unconditional stability of the cascode amplifier.

3. The cascode amplifier of claim 1, wherein:
the frequency of instability is determined in the absence of the stability compensation network.

4. The cascode amplifier of claim 3, wherein:
a resonant frequency of the stability compensation LC resonator is substantially equal to the frequency of instability.

5. The cascode amplifier of claim 1, wherein:
the stability compensation LC resonator is configured not to substantially affect in-band gain and noise figure performances of the cascode amplifier.

6. The cascode amplifier of claim 1, wherein:
the values of the inductor and capacitor of the stability compensation LC resonator are further selected to provide a magnitude of a k-factor or μ-factor calculated from an equivalent two-port scattering parameters of the cascode amplifier to be strictly greater than one for the provision of unconditional stability of the cascode amplifier.

7. The cascode amplifier of claim 6, wherein:
the values of the inductor and capacitor of the stability compensation LC resonator are derived from an iterative process that optimizes:
the magnitude of the k-factor or μ-factor for provision of the unconditional stability, and
an in-band RF performance of the cascode amplifier, including a gain and a noise figure.

8. The cascode amplifier of claim 7, wherein:
the iterative process includes an initial set of the values that include:
an initial value of the inductor that is in a range from 20 picohenries to 1000 picohenries, and
an initial value of the capacitor that is in a range from 20 femtofarads to 300 femtofarads.

9. The cascode amplifier of claim 8, wherein:
the iterative process further includes:
setting the initial value of the inductor to a fixed value within the range from 20 picohenries to 1000 picohenries, and
iteratively changing the value of the capacitor within the range from 20 femtofarads to 300 femtofarads.

10. The cascode amplifier of claim 1, wherein:
the stability compensation LC resonator is tunable, tunability provided by a tunable value of the inductor and/or a tunable value of the capacitor of the stability compensation LC resonator.

11. The cascode amplifier of claim 1, wherein:
the tunable value of the inductor and/or capacitor is provided by a plurality of switches respectively coupled to a plurality of inductors and/or capacitors.

12. The cascode amplifier of claim 11, wherein:
each switch of the plurality of switches is a transistor switch, a size of the transistor switch selected for provision of a specific value of a corresponding ON resistance, and
the ON resistance is configured to reduce a q-factor of the stability compensation LC resonator.

13. The cascode amplifier of claim 1, wherein:
the gate capacitor is a short at a center frequency of operation of the cascode amplifier, and
the frequency of instability is caused by a parasitic gate inductance that is in parallel connection with internal capacitances of the input transistor and the cascode transistor.

14. The cascode amplifier of claim 1, further comprising:
a gate inductor in series connection with the gate capacitor, the gate inductor configured to boost an in-band gain of the cascode amplifier, and
the frequency of instability is predominantly caused by the gate inductor.

15. The cascode amplifier of claim 14, wherein:
the frequency of instability is further caused by a parasitic gate inductance that is in series connection with the series connected gate inductor and gate capacitor.

16. (canceled)

17. The cascode amplifier of claim 14, wherein:
values of the gate inductor and gate capacitor are selected to provide an impedance of the series connected gate inductor and gate capacitor that is substantially greater than zero at frequencies of the in-band.

18. The cascode amplifier of claim 14, further comprising:
a resistor connected in parallel with the gate inductor, the resistor configured to widen an in-band frequency range of the boost.

19. The cascode amplifier of claim 14, wherein:
a value of the gate inductor is tunable.

20. The cascode amplifier of claim 19, wherein:
a value of the gate inductor and/or gate capacitor is tuned to provide an amount of boost of the in-band gain of the cascode amplifier.

21. The cascode amplifier of claim 19, wherein:
a value of the gate inductor and/or gate capacitor is tuned to provide an amount of out of band rejection of the cascode amplifier.

22. The cascode amplifier of claim 1, wherein:
the cascode transistor is an output transistor of the cascode amplifier that is coupled to a supply voltage through a load inductor.

23. The cascode amplifier of claim 1, wherein:
the cascode amplifier comprises a plurality of series connected cascode transistors that includes the cascode transistor, and
the cascode transistor is different from an output transistor of the cascode amplifier.

24. The cascode amplifier of claim 14, wherein:
the cascode transistor is an output transistor of the cascode amplifier that is coupled to a supply voltage through a load inductor.

25. The cascode amplifier of claim 14, wherein:
the cascode amplifier comprises a plurality of series connected cascode transistors that includes the cascode transistor, and
the cascode transistor is different from an output transistor of the cascode amplifier.

26.-30. (canceled)
